(19) United States
(12) Patent Application Publication
(10) Pub. No.: US 2025/0069945 A1
(43) Pub. Date: Feb. 27, 2025

(54) METHODS OF PREPARING SILICON-ON-INSULATOR STRUCTURES USING EPITAXIAL WAFERS

(71) Applicant: GlobalWafers Co., Ltd., Hsinchu (TW)

(72) Inventors: Qingmin Liu, Glen Carbon, IL (US); Xiaofei Lu, Chesterfield, MO (US); Jeffrey L. Libbert, OFallon, MO (US)

(21) Appl. No.: 18/454,895

(22) Filed: Aug. 24, 2023

(51) Int. Cl. H01L 21/762; C30B 15/20; C30B 29/06; C30B 33/02; H01L 21/02; H01L 21/324

(52) U.S. Cl. CPC H01L 21/76251; C30B 15/206; C30B 29/06; C30B 33/02; H01L 21/02532; H01L 21/324

(57) ABSTRACT

A method of preparing a silicon-on-insulator structure includes forming an epitaxial silicon layer on a front surface of a single crystal silicon donor substrate, forming a dielectric layer on the epitaxial silicon layer to thereby form an epitaxial donor structure including the single crystal silicon donor substrate, the epitaxial silicon layer, and the dielectric layer, bonding the dielectric layer of the epitaxial donor structure to a front surface of a handle structure, the handle structure including a single crystal semiconductor handle substrate, to thereby form a bonded structure including the handle structure, the dielectric layer, the epitaxial silicon layer, and the single crystal silicon donor substrate, and removing the single crystal silicon donor substrate and a portion of the epitaxial silicon layer from the bonded structure to thereby form the silicon-on-insulator structure including the handle structure, the dielectric layer, and a silicon device layer.

### FIELD

The field relates generally to silicon-on-insulator structure manufacture, and more particularly, to methods of preparing silicon-on-insulator structures having thin silicon device layers transferred from epitaxial donor substrates.

### BACKGROUND

Single crystal silicon, which is a starting material for the fabrication of semiconductor electronic devices (e.g., microelectronic devices), is commonly prepared by growing a single crystal silicon ingot by the Czochralski (“CZ”) method. In this method, polycrystalline silicon is charged to a crucible and melted, a seed crystal is brought into contact with the molten silicon, and a single crystal ingot is grown by slow extraction. Other single crystal growth techniques, such as the float zone method, may also be utilized to produce single crystal silicon ingots. The single crystal silicon ingot is trimmed and ground to have one or more flats or notches for proper crystal orientation in subsequent procedures, and is then sliced into individual single crystal silicon wafers.

Silicon wafers may be utilized in the preparation of layered silicon-insulator-semiconductor structures, also referred to as silicon-on-insulator (SOI) structures, that facilitate reducing parasitic capacitance and improving performance of the end device. An SOI structure includes a semiconductor handle wafer, a device layer, and an insulating dielectric film (e.g., an oxide layer) between the handle wafer and the device layer. The device layer is typically a thin layer of single crystal silicon. The semiconductor handle wafer may be made of single crystal silicon, or other suitable semiconductor materials, such as germanium, silicon carbide, silicon germanium, gallium arsenide, and other alloys of Group III and Group V elements, such as gallium nitride or indium phosphide, or alloys of Group II and Group VI elements, such as cadmium sulfide or zinc oxide.

An example process of making an SOI structure includes forming a dielectric layer (e.g., an oxide layer) on a polished front surface of a donor wafer made of single crystal silicon. Particles (e.g., hydrogen ions or a combination of hydrogen and helium ions) are implanted at a specified depth beneath the front surface of the donor wafer. The implanted particles form a cleave plane in the donor wafer at the specified depth at which they were implanted. The surface of the donor wafer may be cleaned to remove organic compounds deposited on the wafer during the implantation process.

The front surface of the donor wafer is then bonded to a handle wafer to form a bonded structure through a hydrophilic bonding process. In some processes, the donor wafer and the handle wafer are bonded together by exposing the surfaces of the wafers to a plasma containing, for example, oxygen or nitrogen. Exposure to the plasma modifies the structure of the surfaces in a process often referred to as surface activation. The wafers are then pressed together and a bond is formed therebetween. The donor wafer is thereafter separated (i.e., cleaved) along the cleave plane from the bonded structure to form the SOI structure.

The resulting SOI structure includes a thin layer of silicon (the portion of the donor wafer remaining after cleaving) disposed atop the dielectric layer and the handle wafer. The thin layer of silicon forms the device layer of the SOI structure. However, the cleaved surface of the thin layer of silicon typically has a rough surface that is ill-suited for end-use applications. The damage to the surface may be the result of the particle implantation and the resultant dislocations in the crystal structure of the silicon. Accordingly, additional processing may be required to smooth the cleaved surface.

Known methods used to smooth and thin the surface layer of silicon to form the silicon device layer having a desired thickness and roughness include combinations of annealing and chemical mechanical polishing. These smoothing processes provide less than optimal surface roughness and/or thickness uniformities for certain SOI applications, such as extremely thin SOI (ETSOI) applications or applications requiring fully depleted transistor gates, in which surface roughness and thickness uniformity requirements are typically more stringent than other SOI applications. For example, industry specifications for partially depleted SOI (PDSOI) applications permit a top layer thickness uniformity of 30 angstroms (Å) or more, while fully depleted SOI (FDSOI) applications require a top layer thickness uniformity of 10 Å or less. Accordingly, a need exists for SOI processing methods that enable the production of SOI structures with silicon device layers having improved surface roughness and thickness uniformity.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

In one aspect, a method of preparing a silicon-on-insulator structure includes forming an epitaxial silicon layer on a front surface of a single crystal silicon donor substrate, forming a dielectric layer on the epitaxial silicon layer to thereby form an epitaxial donor structure including the single crystal silicon donor substrate, the epitaxial silicon layer, and the dielectric layer, bonding the dielectric layer of the epitaxial donor structure to a front surface of a handle structure, the handle structure including a single crystal semiconductor handle substrate, to thereby form a bonded structure including the handle structure, the dielectric layer, the epitaxial silicon layer, and the single crystal silicon donor substrate, and removing the single crystal silicon donor substrate and a portion of the epitaxial silicon layer from the bonded structure to thereby form the silicon-on-insulator structure including the handle structure, the dielectric layer, and a silicon device layer.

In another aspect, a silicon-on-insulator structure includes a handle structure including a handle substrate made of single crystal semiconductor material, a dielectric layer in interfacial contact with a front surface of the handle structure, and a silicon device layer in interfacial contact with the dielectric layer. The silicon-on-insulator structure is prepared by a method that includes forming an epitaxial silicon layer on a front surface of a single crystal silicon donor substrate, forming the dielectric layer on the epitaxial silicon layer to thereby form an epitaxial donor structure including the single crystal silicon donor substrate, the epitaxial silicon layer, and the dielectric layer, bonding the dielectric layer of the epitaxial donor structure to the front surface of the handle structure to thereby form a bonded structure including the handle structure, the dielectric layer, the epitaxial silicon layer, and the single crystal silicon donor substrate, and removing the single crystal silicon donor substrate and a portion of the epitaxial silicon layer from the bonded structure to thereby form the silicon-on-insulator structure.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 depicts an example silicon-on-insulator structure.

FIG. 2 depicts an example handle substrate that may be used in the silicon-on-insulator structure of FIG. 1.

FIG. 3 depicts an example donor substrate that may be used in the silicon-on-insulator structure of FIG. 1.

FIG. 4 depicts an example epitaxial donor substrate that includes the donor substrate of FIG. 3 and an epitaxial silicon layer formed on a front surface thereof.

FIG. 5 depicts an example epitaxial donor structure that includes the epitaxial donor substrate of FIG. 4 and a dielectric layer formed on a front surface thereof.

FIG. 6 depicts the epitaxial donor structure of FIG. 5, with a cleave plane formed in the epitaxial silicon layer.

FIG. 7 depicts a bonded structure including the handle structure of FIG. 2 bonded to the epitaxial donor structure of FIG. 6.

FIG. 8 is an atomic force microscopy image of a transferred silicon device layer following a thermal smoothing anneal, showing nanometer-sized recesses formed in the device layer that affect surface roughness.

FIG. 9 is an atomic force microscopy image of a transferred silicon device layer following a thermal smoothing anneal, showing that the nanometer-sized recesses that affect surface roughness did not form in the silicon device layer.

Corresponding reference numerals used throughout the drawings indicate corresponding parts.

### DETAILED DESCRIPTION

Silicon-on-insulator (SOI) structures and methods of preparing SOI structures having a top silicon device layer are described herein. Example SOI structures also include a handle substrate, which may be made of single crystal silicon or another suitable semiconductor material, and a dielectric layer (e.g., a buried oxide layer) between the handle substrate and the top silicon device layer. Devices are built on and/or in the top silicon device layer of the SOI structure, and the dielectric layer acts as an electrically insulating layer to facilitate reducing leakage to the underlying handle substrate. To prepare the SOI structure, the dielectric layer may be formed on a front surface of a donor substrate made of single crystal silicon material, and the dielectric layer is then bonded to the handle substrate. The donor substrate is then partially removed (e.g., by cleaving) from the bonded structure to achieve layer transfer of the dielectric layer and a thin layer of silicon on the handle substrate.

In example embodiments, the top silicon device layer of the SOI structure is “ultra-thin” (e.g., having a thickness of between 10 to 25 nanometers), which enables the SOI structure to be used in fully depleted SOI (FDSOI) applications, such as in the production of low power, high performance metal-oxide-semiconductor field-effect transistors (MOSFETs) and complementary metal-oxide-semiconductor (CMOS) integrated circuits. In these applications, the ultra-thin silicon device layer enables the silicon under the body of the transistor, or the transistor gate, to be fully depleted of charges. Methods of preparing FDSOI structures therefore include transferring thin layers of silicon from the donor substrate to the handle substrate, for example, by cleaving the donor substrate along a cleave plane formed by implanting hydrogen and/or helium ions at a shallow depth below the front surface of the donor substrate.

Following layer transfer, the silicon device layer of the FDSOI structure typically has a rough surface and/or uneven topology that is not suitable for FDSOI device fabrication. The surface roughness and thickness uniformity directly affect the ability to control the threshold voltage (Vₜ) and performance of a low power MOSFET or CMOS device. Suitably, the silicon device layer in the final FDSOI structure has a thickness variation of +/−10 angstroms (Å) or less and a root mean square (RMS) surface roughness below about 0.2 nm as measured with scan sizes of from about 1 micrometers (μm)×about 1 μm to about 30 μm×about 30 μm. Surface roughness may be measured using an atomic force microscopy (AFM) tool, and thickness variation may be measured using a differential reflective microscopy (DRM) tool.

Additional processing techniques are commonly utilized to thin and smooth the transferred silicon device layer in FDSOI manufacture. For example, the transferred silicon device layer may be subjected to a chemical mechanical polishing (“CMP”) operation that typically involves the immersion of the FDSOI structure in an abrasive slurry and polishing of one or both surfaces the substrate by a polymeric pad, whereby through a combination of chemical and mechanical work the surface of the silicon device layer is smoothed to a desired surface roughness. A problem with CMP, however, is that the thickness uniformity of the FDSOI structure cannot be adequately controlled. The FDSOI structure may additionally and/or alternatively be annealed at elevated temperatures in an inert gas and/or reducing gas to smooth the silicon device layer, but this technique introduces other issues such as dewetting and slip. Moreover, these additional smoothing techniques are typically used combination, which increases costs and introduces manufacturing inefficiencies as the FDSOI must be subjected to multiple operations in an effort to achieve the targeted thickness uniformity and surface roughness of the silicon device layer.

Example embodiments described herein provide a cost-effective, practical approach to achieving the targeted thickness uniformity and surface roughness in the top silicon device layer of the FDSOI structure, and facilitate avoiding at least some of the disadvantages associated with existing FDSOI manufacturing processes. In the example embodiments, layers of silicon are transferred to the handle substrate from epitaxial donor wafers that include an epitaxial silicon layer formed (e.g., by chemical vapor deposition) on a single crystal silicon donor wafer. As demonstrated herein, FDSOI device layers derived from epitaxial silicon layers have improved surface roughness post-smoothing (e.g., post-anneal) as compared to device layers derived from conventional single crystal silicon donor wafers. In particular, comparative AFM analysis of thin silicon layers transferred from standard single crystal silicon donor wafers and from epitaxial donor wafers shows that the thin silicon layers transferred from standard wafers have nanometer-sized recesses after a smoothing anneal process, while the thin silicon layers transferred from the epitaxial donor wafers lack these nanometer-sized recesses after the smoothing anneal. The nanometer-sized recesses affect the surface roughness of the thin silicon layers, and additional smoothing (e.g., CMP) is required to eliminate these recesses. The FDSOI silicon device layers that are derived from epitaxial silicon layers and lack these nanometer-sized recesses may achieve targeted thickness uniformity and surface roughness for FDSOI device fabrication post-anneal, thus negating the need for additional smoothing operations (e.g., CMP) that are typically performed on the device layer in conjunction with the smoothing anneal. Thereby, at least some of the disadvantages associated with the additional smoothing techniques may be avoided and the FDSOI structure can be prepared in a more efficient and cost-effective manner.

Without being bound by a particular theory, it is believed that the nanometer-sized recesses in the device layers derived from conventional single crystal silicon wafers form as a result of an interaction of the smoothing anneal process with some aspect of the silicon wafer that is not present in an epitaxial silicon layer of an epitaxial donor wafer. Suitably, the epitaxial silicon layers are free of oxygen and nitrogen, which are not introduced when forming the epitaxial silicon layer. Moreover, comparative AFM analysis between epitaxial donor wafers shows that the oxygen concentration, presence of nitrogen dopant, and/or slicing angle of the silicon donor wafers on which the epitaxial silicon layer is formed to prepare the epitaxial donor wafer may affect the post-anneal surface roughness of the device layer transferred therefrom. In particular, the formation of the nanometer-sized recesses may be controlled by the oxygen concentration, nitrogen concentration, and/or slicing angle of the silicon wafer on which the epitaxial silicon layer is formed. Accordingly, in various embodiments, the silicon donor wafers used to prepare example epitaxial donor wafers has an interstitial oxygen concentration of less than 2.5×10¹⁷ atoms/cm³. Additionally and/or alternatively, the silicon donor wafers used to prepare example epitaxial donor wafers are substantially free of nitrogen as dopant. Additionally and/or alternatively, the silicon donor wafers used to prepare example epitaxial donor wafers are sliced substantially on-axis from a single crystal silicon ingot.

The use of the example epitaxial donor wafers described herein for FDSOI structure manufacture therefore produces a silicon device layer having an improved surface roughness after relatively minimal smoothing is performed on the device layer, which in turn limits or eliminates additional smoothing processing that is otherwise needed to achieve the targeted surface roughness of the silicon device layer for further FDSOI device fabrication. In certain embodiments, CMP of the transferred silicon device layer may be eliminated while still obtaining the desired surface roughness of the silicon device layer, which is advantageous as CMP degrades the thickness uniformity of the FDSOI structure. Accordingly, methods described herein and SOI structures prepared by these methods facilitate increasing the efficiency of the SOI manufacturing by achieving SOI characteristics (e.g., surface roughness and/or thickness uniformity) within targeted specifications while minimizing the processing required to do so.

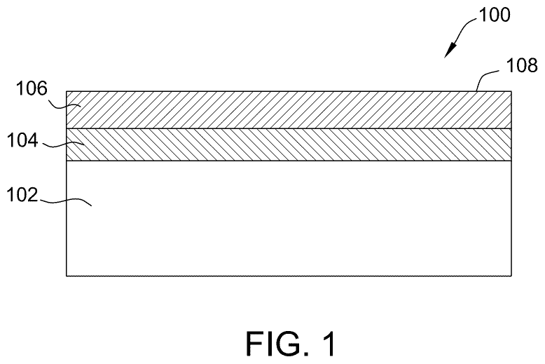

Referring now to the drawings, FIG. 1 depicts an example multilayer structure 100 that includes a semiconductor handle substrate or wafer 102, a dielectric layer 104 (also referred to as a buried oxide or BOX layer) disposed on (e.g., bonded to) the handle substrate 102, and a device layer 106 disposed on the dielectric layer. The device layer 106 may be in interfacial contact with the dielectric layer 104. The dielectric layer 104 may be in interfacial contact with a surface of the handle substrate 102 or may be in interfacial contact with another layer sandwiched between the handle substrate 102 and the dielectric layer 104.

The handle substrate 102 may be made of any suitable semiconductor material. For example, the handle substrate 102 may be a single crystal semiconductor wafer. In various embodiments, the handle substrate 102 may be made of single crystal silicon, or other suitable semiconductor materials, such as germanium, silicon carbide, silicon germanium, gallium arsenide, other alloys of Group III and Group V elements, such as gallium nitride or indium phosphide, alloys of Group II and Group VI elements, such as cadmium sulfide or zinc oxide, and combinations thereof.

The dielectric layer 104 acts as an electrical insulator layer between the device layer 106 and the handle substrate 102 to minimize or eliminate leakage currents, lower parasitic capacitance, and otherwise improve the performance of the end device. The material used for the dielectric layer 104 may vary depending on the intended application of the SOI structure 100. The dielectric layer 104 may include an oxide or a nitride film. In some examples, the SOI structure includes a silicon dioxide (SiO₂) in part or in whole as the dielectric layer 104. In other examples, the dielectric layer 106 may include a material selected from a group consisting of silicon dioxide, silicon nitride, silicon oxynitride, hafnium oxide, titanium oxide, zirconium oxide, lanthanum oxide, barium oxide, aluminum oxide, aluminum nitride, and any combination thereof. The dielectric layer 104 may have any suitable thickness. For example, the thickness of the dielectric layer 104 may be, for example, between about 10 nanometers (nm) to about 10 micrometers (μm). In some embodiments, the thickness of the dielectric layer 104 is greater than or equal to about 100 nm, such as between about 100 nm to about 1 μm, or between about 100 nm to about 300 nm. In other embodiments, the dielectric layer 104 may be relatively thin and has a thickness less than about 100 nm, such as less than or equal to about 50 nm, or less than or equal to about 25 nm. For example, a relatively thin dielectric layer 104 may have a thickness between about 10 nm to about 50 nm, such as between about 10 nm to about 25 nm, or may have a thickness less than or equal to about 10 nm. The dielectric layer 104 may be bonded to the handle substrate 102, for example, where the dielectric layer 104 is formed on a donor wafer from which the device layer 106 is transferred. In some embodiments, the dielectric layer 104 may be formed of multiple dielectric layers. For example, the dielectric layer 104 may include a first dielectric layer formed on the handle substrate 102 and a second dielectric layer bonded to the first dielectric layer, where the second dielectric layer is formed on a donor wafer from which the device layer 106 is transferred.

The device layer 106 is the portion of the multilayer structure 100 upon or in which microelectronic devices are formed. In particular, the device layer 106 has an exposed or outer surface 108 that defines a top surface of the SOI structure 100 upon or in which microelectronic devices are formed. In the example embodiment, the device layer 106 is made of silicon, and the multilayer structure 100 is a silicon-on-insulator (SOI) structure having the silicon device layer 106. Thus, the multilayer structure 100 may interchangeably be referred to herein as an SOI structure 100. Although the device layer 106 is described throughout the present disclosure as a silicon layer, the device layer 106 may additionally and/or alternatively include other semiconductor layers or multiple layers including, for example and without limitation, silicon, germanium, gallium arsenide, aluminum nitride, silicon germanium, gallium nitride, and combinations thereof.

In example embodiments described herein, the SOI structure 100 has a relatively thin device layer 106 that may make the SOI structure suitable for fully depleted SOI (FDSOI) applications. In various embodiments, the device layer 106 has a thickness less than about 100 nm, such as less than or equal to about 50 nm, or less than or equal to about 25 nm. For example, the device layer 106 may have a thickness between about 10 nm to about 100 nm, such as between about 10 nm to about 50 nm, or between about 10 nm to about 25 nm, or may have a thickness less than or equal to about 10 nm. In example embodiments, the device layer 106 is also characterized by having a surface roughness and/or thickness uniformity to facilitate production of FDSOI devices using the SOI structure 100. For example, the outer surface 108 of the device layer 106 may have a root mean square (RMS) roughness of less than or equal about 0.2 nm, or less than or equal to about 0.1 nm, as measured by AFM with scan sizes of from about 1 μm×about 1 μm to about 30 μm×about 30 μm. The device layer 106 may also have a thickness variation, as measured by DRM, of +/−10 A or less, such as +/−9 Å or less, or +/−8 Å or less.

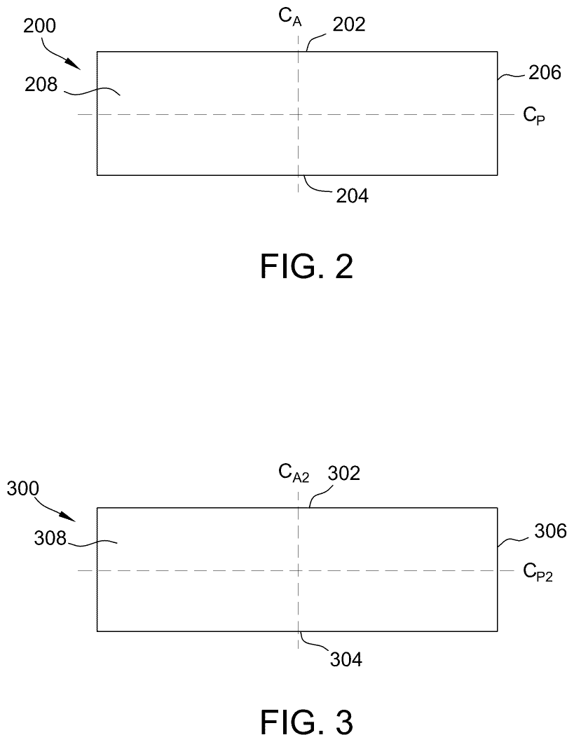

With additional reference to FIGS. 2-7, example methods of preparing the silicon-on-insulator structure 100 will now be described.

FIG. 2 depicts a semiconductor handle substrate 200 that may be used as the handle substrate 102 shown in FIG. 1. The terms “substrate” and “wafer” may be used interchangeably. The handle substrate 200 may be made of any suitable semiconductor material. For example, the handle substrate 200 may be a single crystal semiconductor wafer. In various embodiments, the handle substrate 200 may be made of single crystal silicon, or other suitable semiconductor materials, such as germanium, silicon carbide, silicon germanium, gallium arsenide, other alloys of Group III and Group V elements, such as gallium nitride or indium phosphide, alloys of Group II and Group VI elements, such as cadmium sulfide or zinc oxide, and combinations thereof.

In certain embodiments, the handle substrate 200 is a single crystal semiconductor wafer (e.g., single crystal silicon wafer) sliced from a single crystal ingot grown in accordance with CZ crystal growing methods or float zone growing methods. Wafers, such as single crystal silicon wafers, for use as the handle substrate 200 may be obtained from commercial suppliers, such as GlobalWafers Co., Ltd., Taiwan. The wafers may be sliced from an ingot using any suitable technique (e.g., a wire saw operation). After slicing, the wafers may be lapped, etched, polished and/or cleaned by suitable techniques. The handle substrate 200, e.g., a single crystal silicon handle substrate, may have a mirror-polished surface finish that is free from surface defects, such as scratches and large particles. For example, the handle substrate 200 may be subjected to a CMP operation such that a front surface 202, and optionally a back surface 204, of the substrate are smoothed to a targeted shape and flatness.

The handle substrate 200 may have interstitial oxygen in any suitable concentration that is generally achieved by the CZ or float zone growing methods. For example, the handle substrate may have an interstitial oxygen concentration of between 1×10¹⁶ atoms/cm³ to about 5×10¹⁸ atoms/cm³. Interstitial oxygen concentration may be measured according to SEMI MF 1188-1105.

The handle substrate 200 may have any resistivity obtainable by the CZ or float zone methods. The resistivity of the handle substrate 200 may vary based on the requirements of the end use/application of the SOI structure 100. The resistivity may vary from milliohm or less to megaohm or more. High resistivity handle substrates 200 may have a minimum bulk resistivity of at least about 500 Ohm-cm, such as between about 500 Ohm-cm to about 100,000 Ohm-cm. Low resistivity handle substrates 200 may have a minimum bulk resistivity of below (less than or equal to) about 100 Ohm-cm, such as between about 1 Ohm-cm to about 100 Ohm-cm. Methods for preparing wafers of varying resistivities are known in the art, and wafers having a desired resistivity may be obtained from commercial suppliers, such as Global Wafers Co., Ltd., Taiwan.

In some embodiments, the handle substrate 200 may include a p-type or an n-type dopant. Suitable p-type dopants include boron, gallium, or combinations thereof. Suitable n-type dopants include phosphorus, antimony, arsenic, or combinations thereof. The dopant concentration in the handle substrate 200 may be selected based on the desired resistivity of the handle substrate. In some embodiments, the handle substrate 200 is undoped.

The handle substrate 200 includes two major, generally parallel surfaces. One of the surfaces is the front surface 202, and the other surface is the back surface 204. The handle substrate 200 also includes a circumferential edge 206 joining the front surface 202 and the back surface 204, a bulk region 208 between the front surface 202 and the back surface 204, and a central plane C_{P} between the front surface 202 and the back surface 204. The handle substrate 200 additionally includes an imaginary central axis C_{A} substantially perpendicular to the central plane C_{P}.

A radial length of the handle substrate 200 is measured as the distance between the central axis C_{A} and the circumferential edge 206. A diameter of the handle substrate 200 is measured across the circumferential edge 206. The handle substrate 200 may have any suitable nominal diameter, such as a diameter of at least about 150 mm, at least about 200 mm, at least about 300 mm, or at least about 450 mm. The handle substrate 200 also has a thickness measured as a distance between the front surface 202 and the back surface 204. The handle substrate 200 may have any suitable thickness. For example, the thickness of the handle substrate 200 may be between about 100 μm to about 5000 μm, such as between about 250 μm to about 1500 μm, between about 300 μm and about 1000 μm, or between about 500 μm to about 1000 μm. The handle substrate 200, e.g., a silicon wafer, may have some total thickness variation (TTV), warp, and/or bow; such that the midpoint between every point on the front surface 202 and every point on the back surface 204 may not precisely fall within a plane. As a practical matter, however, the TTV, warp, and bow are typically so slight that to a close approximation the midpoints can be said to fall within the imaginary central plane C_{P} which is approximately equidistant between the front surface 202 and the back surface 204.

In some embodiments, an interfacial layer of material suitable for the intended application of the SOI structure 100 may be formed on the front surface 202 of the handle substrate 200. Prior to the formation of any interfacial layer on the handle substrate 200, or prior to any subsequent operation described herein to prepare the SOI structure 100, the handle substrate may subjected to a pre-treatment operation that includes exposing the surfaces 202 and 204 to an ambient atmosphere comprising reducing agents and/or etching agents to clean the substrate 200 and remove contaminants, such as organic contaminants and boron, aluminum, phosphorus, and the like, from the surfaces 202 and 204. After the pre-treatment operation and/or the forming of any interfacial layer on the handle substrate 200, the exposed surfaces may be subsequently planarized to reduce a surface roughness and optimize warp and bow of the handle substrate for subsequent operations in producing the SOI structure 100. For example, the handle substrate 200 may be subjected to a polishing operation, such as a CMP operation. In addition to polishing, cleaning of the substrate 200 may optionally be performed. If desired, the handle substrate 200 can be cleaned, for example, in a standard SC1 and/or SC2 solution.

In some embodiments, an interfacial semiconductor layer or charge trapping layer may be formed on the front surface 202 of the handle substrate 200, such that the SOI structure 100 shown in FIG. 1 includes a charge trapping layer between the handle substrate 102 and the dielectric layer 104. Semiconductor material that may be used to form the charge trapping layer includes any suitable material that is capable of forming a highly defective layer in the SOI structure 100 between the dielectric layer 104 and the handle substrate 102. Such semiconductor materials include polycrystalline semiconductor materials and amorphous semiconductor materials. Semiconductor materials that may be polycrystalline or amorphous include, for example, silicon (Si), silicon germanium (SiGe), silicon doped with carbon or silicon carbide (SiC), and germanium (Ge). Silicon germanium includes an alloy of silicon germanium in any molar ratio of silicon and germanium. The term “polycrystalline” denotes a semiconductor material comprising small semiconductor crystals having random crystal orientations. The term “amorphous” denotes a semiconductor material that is in non-crystalline allotropic form, which lacks short range and long range order. An interfacial semiconductor layer or charge trapping layer may be deposited onto the front surface 202 of the handle substrate 200 by any suitable means. For example, the semiconductor material may be deposited using metalorganic chemical vapor deposition (MOCVD), physical vapor deposition (PVD), chemical vapor deposition (CVD), low pressure chemical vapor deposition (LPCVD), plasma enhanced chemical vapor deposition (PECVD), or molecular beam epitaxy (MBE). The deposited semiconductor material may be polycrystalline or amorphous, depending on the desired end form of the semiconductor layer 210.

In some embodiments, an interfacial dielectric layer (e.g., silicon oxide, silicon nitride, or silicon oxynitride) may be formed on the front surface 202 of the handle substrate 200. If an interfacial semiconductor layer is also formed on the handle substrate 200, the interfacial dielectric layer may be formed prior to and/or after forming the semiconductor layer. The interfacial dielectric layer may be formed by suitable techniques, such as those discussed below for the dielectric layer 502, including thermal oxidation or chemical vapor deposition (CVD). The interfacial dielectric layer may be used to form, at least partially, the dielectric layer 104 of the SOI structure 100.

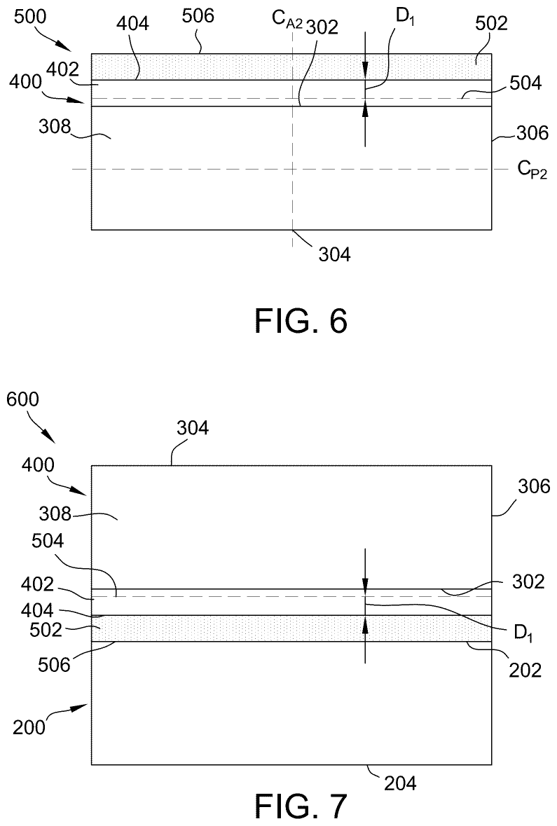

The handle substrate 200, optionally having one or more interfacial layers formed on the front surface 202 thereof, may also be referred to herein as a handle structure 200. After operations to prepare the handle structure 200 for use in preparing the SOI structure 100 have been performed, the handle structure 200 is bonded to an epitaxial donor structure 500 (shown in FIGS. 5 and 6) to produce a bonded structure 600 (shown in FIG. 7) that is subsequently processed to produce the SOI structure 100 shown in FIG. 1. This sequence will be described further below.

FIG. 3 depicts a donor substrate 300 from which the device layer 106 in the SOI structure 100 is derived. In the example embodiment, the donor substrate 300 is made of single crystal silicon, which corresponds to the single crystal silicon material that forms the device layer 106. Although the donor substrate 300 is described throughout the present disclosure as a single crystal silicon donor substrate, the donor substrate 300 may additionally and/or alternatively include any suitable single crystal semiconductor material depending on the intended application for the SOI structure 100 and the desired material for the device layer 106. For example, the donor substrate 300 may be made of silicon, germanium, gallium arsenide, aluminum nitride, silicon germanium, gallium nitride, and combinations thereof.

In the example embodiment, the single crystal silicon donor substrate 300 is a single crystal silicon wafer sliced from a single crystal ingot grown in accordance with CZ or float zone growing methods. Single crystal silicon wafers for use as the donor substrate 300 may be obtained from commercial suppliers, such as GlobalWafers Co., Ltd., Taiwan. The wafers may be sliced from an ingot using any suitable technique (e.g., a wire saw operation). In various embodiments, the donor substrate 300 is sliced substantially on-axis from a single crystal silicon ingot. The phrase “substantially on-axis” as used herein to described donor substrates 300 sliced from a single crystal silicon ingot means that the slicing angle at which the donor substrates are sliced has minimal on-axis deviation (e.g., less than +/−0.1°, preferably less than +/−0.07°, in an x-axis direction and in a y-axis direction) from the crystal direction that is normal to the crystallographic orientation of the ingot (i.e., along a central longitudinal axis of the ingot). Although single crystal silicon wafers having any crystallographic orientation (e.g., {100}, {110} or {111}) may be used as the donor substrate 300, {100} silicon wafers will be described to illustrate a donor substrate that is sliced substantially on-axis from the ingot in accordance with the present disclosure. The {100} silicon wafers may, in some implementations, be sliced from a {100} silicon ingot at an angle that deviates from the direction (e.g., at an angle between about 0.1° to about 0.5° off the central longitudinal axis of the ingot in an x-axis and/or y-axis direction). These {100} silicon wafers sliced at an angle that deviates from the direction in the x-axis and/or the y-axis direction may have less haze after being annealed than wafers sliced substantially along (e.g., deviating less than +/−0.1° in the x-axis direction and in the y-axis direction from) the direction. However, as demonstrated herein, post-anneal, nanometer-sized recesses that affect surface roughness are absent from silicon device layers derived from epitaxial silicon layers formed on single crystal silicon donor substrates 300 that have been sliced substantially on-axis from the ingot. These post-anneal, nanometer-sized recesses may otherwise exist where the silicon device layer is derived from a single crystal silicon donor substrate 300 that has been sliced off-axis from an ingot. Accordingly, the donor substrates 300 are, in some embodiments, sliced substantially on-axis from a single crystal silicon ingot. In these embodiments, the on-axis deviation of the slicing angle (i.e., the deviation of the slicing angle from the central longitudinal axis of the ingot in the x-axis direction and in the y-axis direction) at which the donor substrate 300 is sliced from a single crystal silicon ingot is preferably less than +/−0.1°, and more preferably less than +/−0.07°. In some examples, the donor substrates 300 are sliced precisely along (i.e., at an angle that does not deviate in either the x-axis direction or the y-axis direction from) the crystal direction that is normal to the crystallographic orientation of the ingot. For example, {100} silicon wafers used for the donor substrate 300 may be sliced from a {100} silicon ingot precisely along the direction.

As described above for the handle substrate 200, after slicing, the silicon wafers used for the donor substrate 300 may be lapped, etched, polished and/or cleaned by suitable techniques. The donor substrate 300, e.g., a single crystal silicon donor substrate, may have a mirror-polished surface finish that is free from surface defects, such as scratches and large particles. For example, the donor substrate 300 may be subjected to a CMP operation such that a front surface 302, and optionally a back surface 304, of the substrate are smoothed to a targeted shape and flatness. The donor substrate 300 may also be subjected to a pre-treatment operation that includes exposing the surfaces 302 and 304 to an ambient atmosphere comprising reducing agents and/or etching agents to clean the substrate 300 and remove contaminants, such as organic contaminants and boron, aluminum, phosphorus, and the like, from the surfaces 302 and 304.

The donor substrate 300 may have interstitial oxygen in any suitable concentration that is generally achieved by the CZ or float zone growing methods. For example, the donor substrate 300 may have an interstitial oxygen concentration of between 1×10¹⁶ atoms/cm³ to about 5×10¹⁸ atoms/cm³. In certain embodiments, the interstitial oxygen concentration of the donor substrate 300 is less than 2.5×10¹⁷ atoms/cm³. As demonstrated herein, post-anneal, nanometer-sized recesses that affect surface roughness are absent from silicon device layers derived from epitaxial silicon layers formed on single crystal silicon donor substrates 300 that have an interstitial oxygen concentration below the 2.5×10¹⁷ atoms/cm³ threshold. These post-anneal, nanometer-sized recesses may otherwise exist where the silicon device layer is derived from a single crystal silicon donor substrate 300 that has a relatively higher interstitial oxygen concentration.

In some embodiments, the donor substrate 300 may be substantially free of nitrogen as dopant. As demonstrated herein, post-anneal, nanometer-sized recesses that affect surface roughness are absent from silicon device layers derived from epitaxial silicon layers formed on single crystal silicon donor substrates 300 that are substantially free of nitrogen as dopant. These post-anneal, nanometer-sized recesses may otherwise exist where the silicon device layer is derived from a single crystal silicon donor substrate 300 that is doped with nitrogen. The phrase “substantially free of nitrogen as dopant” means that the donor substrate 300 is not intentionally doped with nitrogen. For example, the donor substrate 300 that is substantially free of nitrogen as dopant may be sliced from a single crystal semiconductor ingot (e.g., a single crystal silicon ingot) that is grown without any intentional nitrogen doping. In some embodiments, the donor substrate 300 that is substantially free of nitrogen as dopant may have a nitrogen concentration that is below the detectable limit as measured by secondary ion mass spectrometry (SIMS) (SEMI MF2139). For example, the donor substrate 300 that is substantially free of nitrogen as dopant may have a nitrogen concentration of less than 1×10¹³ atoms/cm³.

The donor substrate 300 may have any resistivity obtainable by the Czochralski or float zone methods. The resistivity of the donor substrate 300 may vary based on the requirements of the end use/application of the SOI structure 100. For example, the donor substrate 300 may be a high resistivity substrate having a minimum bulk resistivity of at least about 500 Ohm-cm, such as between about 500 Ohm-cm to about 100,000 Ohm-cm. Alternatively, in another example, the donor substrate 300 may be a low resistivity substrate having a minimum bulk resistivity of below (less than or equal to) about 100 Ohm-cm, such as between about 1 Ohm-cm to about 100 Ohm-cm.

In some embodiments, the donor substrate 300 may include a p-type or an n-type dopant. Suitable p-type dopants include boron, gallium, or combinations thereof. Suitable n-type dopants include phosphorus, antimony, arsenic, or combinations thereof. The dopant concentration in the donor substrate 300 may be selected based on the desired resistivity of the donor substrate.

The donor substrate 300, similar to the handle substrate 200, includes two major, generally parallel surfaces. One of the surfaces is a front surface 302 (also referred to as a front donor substrate surface, a front donor wafer surface, or a front donor surface), and the other surface is a back surface 304 of the substrate (also referred to as a back donor substrate surface, a back donor wafer surface, or a back donor surface). The donor substrate 300 also includes a circumferential edge 306 joining the front surface 302 and the back surface 304, a bulk region 308 between the front surface 302 and the back surface 304, and a central plane C_{P2} between the front surface 302 and the back surface 304. The donor substrate 300 additionally includes an imaginary central axis C_{A2} substantially perpendicular to the central plane C_{P2}.

A radial length of the donor substrate 300 is measured as the distance between the central axis C_{A2} and the circumferential edge 306. A diameter of the donor substrate 300 is measured across the circumferential edge 306. The donor substrate 300 may have any suitable nominal diameter, such as a diameter of at least about 150 mm, at least about 200 mm, at least about 300 mm, or at least about 450 mm. The donor substrate 300 also has a thickness D₁ measured as a distance between the front surface 302 and the back surface 304. The donor substrate 300 may have any suitable thickness D₁. For example, the thickness D₁ of the donor substrate 300 may be between about 100 μm to about 5000 μm, such as between 250 μm to about 1500 μm, between about 300 μm and about 1000 μm, or between about 500 μm to about 1000 μm. The donor substrate 300, like the handle substrate 200, may have some total thickness variation (TTV), warp, and/or bow, such that the midpoint between every point on the front surface 302 and every point on the back surface 304 may not precisely fall within a plane. As a practical matter, however, the TTV, warp, and bow are typically so slight that to a close approximation the midpoints can be said to fall within the imaginary central plane C_{P2} which is approximately equidistant between the front surface 302 and the back surface 304.

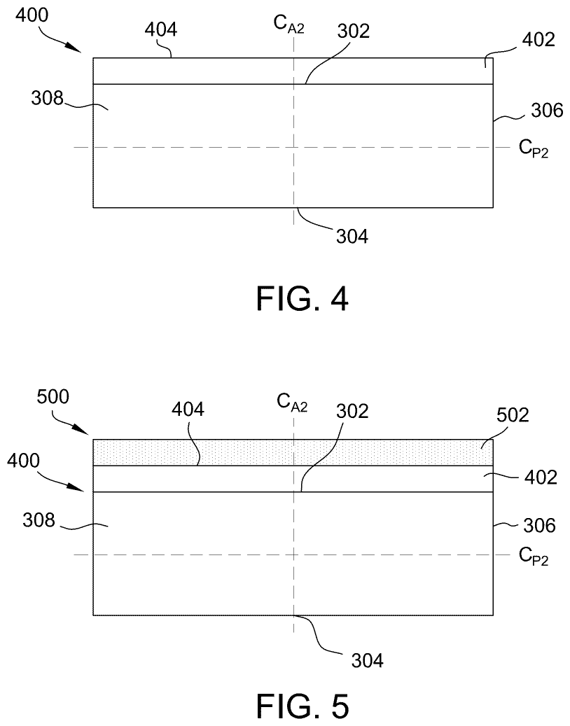

Referring now to FIG. 4, an epitaxial layer 402 is formed on the front surface 302 of the donor substrate 300 to produce an epitaxial donor substrate 400. The device layer 106 of the SOI structure 100 is derived from the epitaxial layer 402. As such, the epitaxial layer 402 is made of the desired material for the device layer 106. In the example embodiment, the epitaxial layer 402 is an epitaxial silicon layer. Although the epitaxial layer 402 is described throughout the present disclosure as an epitaxial silicon layer, the epitaxial layer 402 may additionally and/or alternatively include other semiconductor layers or multiple layers including, for example and without limitation, silicon, germanium, gallium arsenide, aluminum nitride, silicon germanium, gallium nitride, and combinations thereof. The epitaxial layer 402 may be free of oxygen and nitrogen, which are suitably not introduced into the epitaxial layer 402 when formed on the donor substrate 300.

The epitaxial silicon layer 402 also has a suitable thickness to enable layer transfer of the device layer 106. For example, the epitaxial silicon layer 402 may have a thickness of between about 0.5 μm to about 5 μm, such as between about 1 μm to about 3 μm. In various examples, the thickness of the epitaxial silicon layer 402 may be about 0.5 μm, about 1 μm, about 2 μm, about 3 μm, about 4 μm, or about 5 μm.

In some embodiments, the epitaxial silicon layer 402 is deposited on the front surface 302 of the donor substrate 300 by chemical vapor deposition (CVD) in an epitaxial reactor. Suitable epitaxial reactors for depositing the epitaxial silicon layer 402 by CVD include an Epsilon E3000 reactor available from ASM or a Centura reactor available from Applied Materials. The epitaxial silicon layer 402 deposited by CVD has a single crystal lattice structure that is identical to that of the underlying single donor substrate 300. An example epitaxial CVD process may begin by positioning the donor substrate 300 on a susceptor within a reaction chamber of the epitaxial reactor, with the front surface 302 facing away from the susceptor. The susceptor supports the donor substrate 300 during the CVD process and may rotate the donor substrate 300 to facilitate uniform growth of the epitaxial silicon layer 402. A cleaning gas, such as hydrogen or a hydrogen and hydrogen chloride mixture, may be introduced into the reaction chamber and contacts the front surface 302 of the donor to pre-heat and clean the front surface 302. For example, the cleaning gas may remove native oxide from the front surface 302, permitting the epitaxial silicon layer 402 to grow continuously and evenly on the front surface 302 during a subsequent step of the CVD process. The epitaxial CVD process continues by introducing a vaporous silicon source gas, such as silane or a chlorinated silane (e.g., SiCl₄, SiHCl₃, SiH₂Cl₂, SiH₃Cl, or SiH₄), into the reaction chamber which contacts the front surface 302 of the donor substrate 300 to deposit and grow the epitaxial silicon layer 402 on the front surface 302. A carrier gas, such as hydrogen gas, may simultaneously be introduced with the vaporous silicon source gas and contacts the back surface 304. During the epitaxial CVD process, the temperature of the donor substrate 300 is ramped to and maintained at a temperature sufficient to deposit and grow the epitaxial silicon layer 402 on the front surface 302. The temperature may suitably prevent the atmosphere comprising the vaporous silicon source gas from depositing polycrystalline silicon on the donor substrate 300. For example, the temperature of the front surface 302 during CVD deposition may be at least about 900° C., such as between about 1050° C. to about 1150° C. Suitably, the atmosphere in the reaction chamber is controlled during CVD deposition such that no oxidizing or nitriding gases are introduced, and such that the epitaxial silicon layer 402 deposited by the CVD process is substantially free of oxygen and nitrogen (e.g., has an oxygen concentration and a nitrogen concentration that are below the detectable limit).

After the epitaxial silicon layer 402 is formed (e.g., deposited) on the front surface 302 of the donor substrate 300, the exposed surfaces of the epitaxial donor substrate 400 (e.g., an exposed or outer surface 404 of the epitaxial silicon layer 402 and the back surface 304 of the donor substrate 300) may be sufficiently smooth and the epitaxial donor substrate 400 may have acceptable bow and warp, such that a subsequent planarization operation (e.g., CMP) is not required. Accordingly, the epitaxial donor substrate 400 may proceed to further processing for preparing the SOI structure 100 without CMP in some embodiments. In other embodiments, the epitaxial donor substrate 400 may optionally be planarized prior to subsequent operations performed on the donor substrate 400 for preparing the SOI structure 100. For example, the epitaxial donor substrate 400 may be subjected to a polishing operation, such as a CMP operation. In addition or in the alternative to polishing, cleaning of the epitaxial donor substrate 400 may optionally be performed. If desired, the epitaxial donor substrate 400 can be cleaned, for example, in a standard SC1 and/or SC2 solution

Referring now to FIG. 5, after the epitaxial silicon layer 402 is formed on the donor substrate 300, and the donor substrate is optionally polished and/or cleaned, a dielectric layer 502 is formed on the outer surface 404 the epitaxial silicon layer 402 to form an epitaxial donor structure 500. The dielectric layer 502 forms, at least partially, the dielectric layer 104 in the SOI structure 100 shown in FIG. 1. The material used for the dielectric layer 502 may vary depending on the intended application of the SOI structure 100. In various examples, the dielectric layer 502 may include an oxide or a nitride layer. For example, the dielectric layer 502 may include a film of silicon dioxide (SiO₂) in part or in whole. In other examples, the dielectric layer 502 may include a material selected from a group consisting of silicon dioxide, silicon nitride, silicon oxynitride, hafnium oxide, titanium oxide, zirconium oxide, lanthanum oxide, barium oxide, aluminum oxide, aluminum nitride, and any combination thereof.

The dielectric layer 502 may have any suitable thickness which may vary depending on the intended application of the SOI structure 100 and the desired thickness of the dielectric layer 104. For example, as described above for the dielectric layer 104, the thickness of the dielectric layer 502 may be between about 10 nm to about 10 μm. In some embodiments, the thickness of the dielectric layer 502 is greater than or equal to about 100 nm, such as between about 100 nm to about 1 μm, or between about 100 nm to about 300 nm. In other embodiments, the dielectric layer 502 may be relatively thin and has a thickness less than about 100 nm, such as less than or equal to about 50 nm, or less than or equal to about 25 nm. For example, a relatively thin dielectric layer 502 may have a thickness between about 10 nm to about 50 nm, such as between about 10 nm to about 25 nm, or may have a thickness less than or equal to about 10 nm.

In some embodiments, the dielectric layer 502 may include an oxide layer (e.g., silicon dioxide or silicon oxynitride) or a nitride layer (e.g., silicon nitride) that is formed by a suitable layer forming technique performed on the epitaxial donor substrate 400. In some embodiments, forming the dielectric layer 502 may be accomplished by thermal oxidation or nitriding, CVD oxide or nitride deposition, and/or atomic layer deposition. In some embodiments, the dielectric layer 502 may be formed by thermally oxidizing or nitriding the donor substrate 300 in a furnace such as an ASM A400 or an ASM A412. During such processes to form the dielectric layer 502, the temperature may range from 750° C. to 1200° C. in an oxidizing or nitriding ambient. An oxidizing ambient atmosphere may be a mixture of inert gas, such as argon (Ar) or nitrogen gas (N₂), and O₂ gas. The O₂ gas content in the oxidizing ambient during thermal oxidation may vary from 1 to 10 percent, by volume, or higher. In some embodiments, the oxidizing ambient may be up to 100% O₂ by volume (a “dry oxidation”). In some embodiments, the ambient may be an oxidizing and nitriding ambient that includes a mixture of O₂ gas and a nitriding gas, such as ammonia gas, which may be suitable for depositing silicon oxynitride. In some embodiments, the ambient may include a mixture of inert gas, such as Ar or N₂, and oxidizing gases, such as O₂ and water vapor (a “wet oxidation”). In some embodiments, the ambient may include a mixture of inert gas, such as Ar or N₂, and oxidizing gas, such as O₂ and water vapor (a “wet oxidation”), and a nitriding gas, such as ammonia. In some embodiments, the nitriding ambient may comprise a mixture of inert gas, such as Ar or N₂, and a nitriding gas, such as ammonia, which is suitable for depositing silicon nitride.

The dielectric layer 104 and the device layer 106 in the SOI structure 100 shown in FIG. 1 are derived from the epitaxial donor structure 500. In particular, the epitaxial donor structure 500 is brought into intimate contact with and bonded to the handle substrate 200 to produce a bonded structure 600 as shown in FIG. 7, and a portion of the epitaxial donor structure 500 is removed from the bonded structure 600 to transfer the dielectric layer 502, forming the dielectric layer 104, and a portion of the epitaxial silicon layer 402, forming the device layer 106. Removal of the portion of the epitaxial donor structure 500 to achieve layer transfer of the dielectric layer 104 and the device layer 106 on the SOI structure 100 may be accomplished by suitable wafer thinning techniques, such as grinding, lapping, back-side etching, cleaving, or a combination of two or more of these techniques.

In the example embodiment, the bonded structure 600 is cleaved to achieve layer transfer and prepare the SOI structure 100. Referring to FIG. 6, to enable cleave and layer transfer from the epitaxial donor structure 500 onto the SOI structure 100, a cleave plane 504 may be formed in the epitaxial silicon layer 402 of the epitaxial donor structure 500 at a desired depth D₁ measured from the outer surface 404 of the epitaxial silicon layer. The cleave plane 504 may be formed in the epitaxial silicon layer 402 by suitable ion implantation techniques. Ion implantation may include implanting particles or ions through a surface of the epitaxial donor structure 500 (e.g., an exposed or outer surface 506 of the dielectric layer 502 or the back surface 304 of the donor substrate 300) to form the cleave plane 504 in the epitaxial silicon layer 402. In the example embodiment, particles or ions may be implanted through the outer surface 506 of the dielectric layer 502 and the surface 404 of the epitaxial silicon layer 402 to form the cleave pane 504. Ion implantation may be carried out in a commercially available instrument, such as an Applied Materials Quantum or VIISta implanter. Implanted particles or ions include helium (He) ions, hydrogen ions (H and/or H₂), or combinations thereof. Ion implantation is carried out at a density and duration sufficient to form the cleave plane 504 in the epitaxial silicon layer 402 at the desired depth D₁. Implant density may range from about 10¹² ions/cm² to about 10¹⁷ ions/cm², such as from about 10¹⁴ ions/cm² to about 10¹⁷ ions/cm². Implant energies may range from about 1 keV to about 3,000 keV, such as from about 10 keV to about 3,000 keV. The implant density and/or energy may be controlled to achieve a targeted depth D₁ beneath the outer surface 404 of the epitaxial silicon layer 402 that enables a relatively thin device layer 106 to be transferred on the SOI structure 100, as described, for example, in U.S. Pat. No. 10,818,540, issued Oct. 27, 2020, the disclosure of which is hereby incorporated by reference herein in its entirety.

The depth D₁ of the cleave plane 504 is suitably shallower than the thickness of the epitaxial silicon layer 402 which, as described above, may be between about 0.5 μm to about 5 μm. The depth D₁ of the cleave plane 504 may be approximately equal to the desired thickness of the device layer 106 which, as described above, may be between about 10 nm to about 100 nm, or may be less than 10 nm. In other embodiments, however, the depth D₁ of the cleave plane 504 may be slightly larger than the desired thickness of the device layer 106 to compensate for material losses during layer transfer and/or post-transfer smoothing of the device layer 106. For example, the depth D₁ of the cleave plane 504 may be between about 10 nm to about 400 nm, such as between about 10 nm to about 300 nm.

In some embodiments it may be desirable to subject the epitaxial donor structure 500 to a cleaning operation after the implant, for example, a Piranha clean followed by a deionized water rinse and cleaning using a SC1 and/or SC2 solution. The epitaxial donor structure 500 having the cleave plane 504 may also be annealed at a temperature sufficient to thermally activate the cleave plane 504. An example of a suitable annealing tool is a box furnace, such as a Blue M model. The ion-implanted epitaxial donor structure 500 may be annealed at a temperature of, for example, from about 200° C. to about 400° C., and for a duration of, for example, from about 0.5 hours to about 10 hours. The ion-implanted epitaxial donor structure 500 may be thermally annealed at any temperature and duration sufficient to thermally activate the cleave plane 504. The cleaning operations performed on the ion-implanted epitaxial donor structure 500 may be performed before and/or after the thermal anneal to activate the cleave plane 504.

Referring to FIG. 7, the exposed or outer surface 506 of the dielectric layer 502 and the front surface of the handle structure 200 are brought into intimate contact to thereby form the bonded structure 600. The front surface of the handle structure 200 is the front surface 202 of the semiconductor handle substrate 200 in this embodiment. In other embodiments, the front surface of the handle structure 200 to which the outer surface 506 of the dielectric layer 502 is bonded may be an exposed surface of an interfacial layer (e.g., an interfacial dielectric layer) formed on the front surface 202 of the handle substrate 200. The bonded structure 600 includes the epitaxial donor substrate 400, the dielectric layer 502 formed on the front surface 404 of the epitaxial silicon layer 402, and the handle structure 200 in interfacial contact with the dielectric layer 502. To make the surfaces of the dielectric layer 502 and the handle structure 200 hydrophilic and amenable to bonding, plasma surface activation (e.g., oxygen plasma and/or nitrogen plasma surface activation) may be performed on one or both of the dielectric layer and the handle structure using any suitable commercially available plasma activation tool, such as those available from EV Group, e.g., EVG®810LT Low Temp Plasma Activation System. Additionally and/or alternatively, the bonded structure 600 may be subjected to an anneal to strengthen the bond between the handle structure 200 and the dielectric layer 502. For example, the bonded structure 600 may be annealed in a box furnace, such as a Blue M model, at a temperature and for a duration sufficient to solidify the bond between the handle structure 200 and the dielectric layer 502. In some embodiments, the bonded structure 600 is annealed at a temperature of from about 200° C. to about 400° C., and for a duration of from about 0.5 hours to about 10 hours. Thermal annealing of the bonded structure 600 may also contribute to thermally activating the cleave plane 504.

The bonded structure 600 is cleaved to produce the SOI structure 100 shown in FIG. 1. Cleaving may occur according to techniques known in the art. In some embodiments, the bonded structure 600 may be placed in a cleave station affixed to stationary suction cups on one side (e.g., on one of the back surfaces 204, 304) and affixed by additional suction cups on a hinged arm on the other side (e.g., on another one of the back surfaces 204, 304). A crack is initiated near the suction cup attachment and the movable arm pivots about the hinge cleaving the epitaxial donor substrate 400 apart along the cleave plane 504. Cleaving removes a portion of the epitaxial donor substrate 400 along the cleave plane 504 formed in the epitaxial silicon layer 402, thereby transferring the dielectric layer 502 and a portion of the epitaxial silicon layer 402 to respectively form the dielectric layer 104 and the device layer 106 on the SOI structure 100.

In some embodiments, post-layer transfer processing may be utilized to smooth the device layer 106 following layer transfer. For example, after layer transfer, the SOI structure 100 may be subjected to a high temperature anneal, which may also strengthen the bonds between adjacent layers of the SOI structure 100 (e.g., the bond between the transferred device layer 106 and the dielectric layer 104 and/or the bond between the dielectric layer 104 and the handle substrate 102). The high temperature anneal may be performed on multiple SOI structures 100 in a batch furnace to reduce costs, but may be performed on an individual SOI structure 100 in a single wafer processing chamber. An example of a suitable tool for the high temperature anneal is a vertical furnace, such as an ASM A400 or an ASM A412. The high temperature anneal is suitably performed at a temperature and for a duration sufficient to smooth a surface of the silicon device layer 106 and/or strengthen the bonds between adjacent layers in the SOI structure 100. In some embodiments, the SOI structure 100 is annealed at a temperature of greater than or equal to about 950° C., such as between about 1000° C. to about 1200° C., and for a duration of between about 15 minutes to about 10 hours, such as between about 0.5 hours to about 8 hours, or between about 2 to about 4 hours. The high temperature anneal of the SOI structure 100 may, in some embodiments, be performed in the presence of an anneal atmosphere that includes at least one of an inert gas (e.g., argon gas), hydrogen (H₂) gas, and helium gas, or a combination of two or more of these gases. For example, the high temperature anneal may be performed at a temperature of between about 1000° C. to about 1200° C., for a duration of between about 2 hours to about 4 hours, in the presence of argon gas. The high temperature anneal may additionally and/or alternatively be performed in an “active” gas environment, for example, in the presence of nitrogen (N₂) gas, oxygen (O₂) gas, or a combination of N₂ and O₂ gas. A high temperature anneal in an active gas environment may be performed to strengthen the bonds between adjacent layers of the SOI structure 100, but typically will not smooth surfaces of the SOI structure (e.g., the outer surface 108 of the device layer 106).

Following the high temperature anneal, the device layer 106 transferred from the epitaxial donor substrate 400 suitably has improved surface roughness and/or thickness variation as compared to silicon layers transferred from conventional single crystal silicon donor substrates and subjected to the same anneal. In particular, following the anneal, a device layer 106 transferred from an epitaxial donor substrate 400 as described herein is characterized by a lack of nanometer-sized recesses that otherwise form during the anneal and affect the roughness of the surface 108 of the device layer 106, as measured by AFM. These nanometer-sized recesses, which have been discovered in silicon device layers transferred from conventional single crystal silicon donor substrates, require further processing on the transferred device layer to achieve a targeted surface roughness and thickness uniformity. For example, the targeted surface roughness of the outer surface 108 of the device layer 106 may be RMS roughness of less than or equal about 0.2 nm, or less than or equal to about 0.1 nm, as measured by AFM with scan sizes of from about 1 μm×about 1 um to about 30 μm×about 30 μm. The targeted thickness uniformity of the device layer 106 may be a thickness variation, as measured by DRM, of +/−10 Å or less, such as +/−9 Å or less, or +/−8 Å or less. The absence of the post-anneal, nanometer-sized recesses in the device layer 106 transferred from an epitaxial donor substrate 400 as described herein may enable these targeted specifications to be achieved without additional smoothing processes being performed in conjunction with the high temperature anneal, which improves manufacturing efficiency and reduces costs. For example, CMP may be eliminated, which is additionally advantageous as CMP degrades the thickness uniformity of the transferred silicon device layer 106. Moreover, as described above, the epitaxial donor substrate 400 may have certain characteristics that are demonstrated to facilitate the improved surface roughness of the device layer 106 following the anneal. For example, the donor substrate 300 used to prepare an epitaxial donor substrate 400 may have an interstitial oxygen concentration of less than 2.5×10¹⁷ atoms/cm³. Additionally and/or alternatively, the donor substrate 300 may be substantially free of nitrogen as dopant. Additionally and/or alternatively, the donor substrate 300 may be sliced substantially on-axis from a single crystal silicon ingot.

While the device layer 106 transferred from the epitaxial donor substrate 400 suitably has improved surface roughness and/or thickness variation following the anneal, in some embodiments, the SOI structure 100 may be subjected to post-layer transfer smoothing operations in addition to or in the alternative to the high temperature anneal. For example, a polishing operation, such as CMP, may be performed on the SOI structure 100 to planarize one or both of the exposed surfaces of the SOI structure (e.g., the outer surface 108 of the transferred device layer 106). The polishing operation may be performed in addition to (e.g., before and/or after) or in the alternative to the high temperature thermal anneal. For example, a CMP operation may be performed on the transferred device layer 106, followed by the high temperature thermal anneal performed on the SOI structure 100. In other embodiments, CMP is suitably omitted from post-layer transfer smoothing operations performed on the SOI structure 100. Further, in some embodiments, the SOI structure 100 may be subjected to a non-contact smoothing process, also referred to as epitaxial smoothing or “epi-smoothing,” after the high temperature anneal and/or the polishing operation. The epi-smoothing process may further reduce the roughness of the transferred device layer 106 on the SOI structure 100 and/or remove any implant damage of the device layer 106 that was not compensated for by any previous smoothing processes (e.g., in the high temperature thermal anneal and/or the polishing operation). Example epi-smoothing processes are described, for example, in U.S. Pat. No. 9,202,711, issued Dec. 1, 2015, the disclosure of which is hereby incorporated by reference herein in its entirety. The epi-smoothing process is typically performed in a suitable reactor (e.g., an epitaxial deposition reactor) that is operable to heat the SOI structure 100 in a reaction chamber and introduce etchant gases into the reaction chamber that perform work on (e.g., etch) the transferred device layer 106 to further smoothed the outer surface 108. For example, the epi-smoothing process may include positioning the SOI structure 100 in an epi-reactor chamber, heating the chamber to a temperature between 900° C. and 1100° C., introducing gaseous etchant (e.g., hydrogen chloride, HCl, or chlorine and hydrogen gas, H₂) into the chamber, and maintaining temperature and flow of the gaseous etchant for a suitable duration to achieve a targeted surface roughness of the transferred device layer 106.

Following layer transfer of the device layer 106 and any additional post-layer transfer smoothing operations performed on the SOI structure 100, the device layer 106 has a suitable thickness for device fabrication (e.g., FDSOI device fabrication). As described above, the device layer 106 may have a thickness less than about 100 nm, such as less than or equal to about 50 nm, or less than or equal to about 25 nm. For example, the device layer 106 may have a thickness between about 10 nm to about 100 nm, such as between about 10 nm to about 50 nm, or between about 10 nm to about 25 nm, or may have a thickness less than or equal to about 10 nm. In example embodiments, following layer transfer of the device layer 106 and any additional post-layer transfer smoothing operations performed on the SOI structure 100, the device layer 106 has a suitable surface roughness and/or thickness uniformity to facilitate production of FDSOI devices using the SOI structure 100. For example, the outer surface 108 of the device layer 106 may have a root mean square (RMS) roughness of less than or equal about 0.2 nm, or less than or equal to about 0.1 nm, as measured by AFM with scan sizes of from about 1 μm×about 1 μm to about 30 μm×about 30 μm. The device layer 106 may also have a thickness variation, as measured by DRM, of +/−10 Å or less, such as +/−9 Å or less, or +/−8 Å or less.

The SOI structure may subsequently be subjected to further processing based on an intended application use of the SOI structure. For example, an epitaxial layer may be deposited on the outer surface 108 transferred device layer 106. An epitaxial layer deposited on the device layer 106 may include substantially the same electrical characteristics as the underlying device layer. Alternatively, the epitaxial layer deposited on the device layer 106 may include different electrical characteristics as the underlying device layer. An epitaxial layer may comprise a material selected from the group consisting of silicon, silicon carbide, silicon germanium, gallium arsenide, gallium nitride, indium phosphide, indium gallium arsenide, germanium, and combinations thereof. In embodiments where epi-smoothing is performed on the SOI structure 100, the SOI structure may remain in the reactor and be subjected to an epi-deposition process in the same reactor, or the epitaxial layer may be deposited on the device layer 106 in a separate reactor. Depending upon the desired properties of the final device, the epitaxial layer may comprise a dopant, such as one or more p-type dopants (e.g., boron, gallium, aluminum, and/or indium) and/or one or more n-type dopants (e.g., phosphorus, antimony, and/or arsenic). The final SOI structure 100 may additionally and/or alternatively be subjected to end of line metrology inspections and cleaned a final time using typical SC1-SC2 process.

### EXAMPLE

The following non-limiting Example further illustrates the subject matter of the present disclosure.

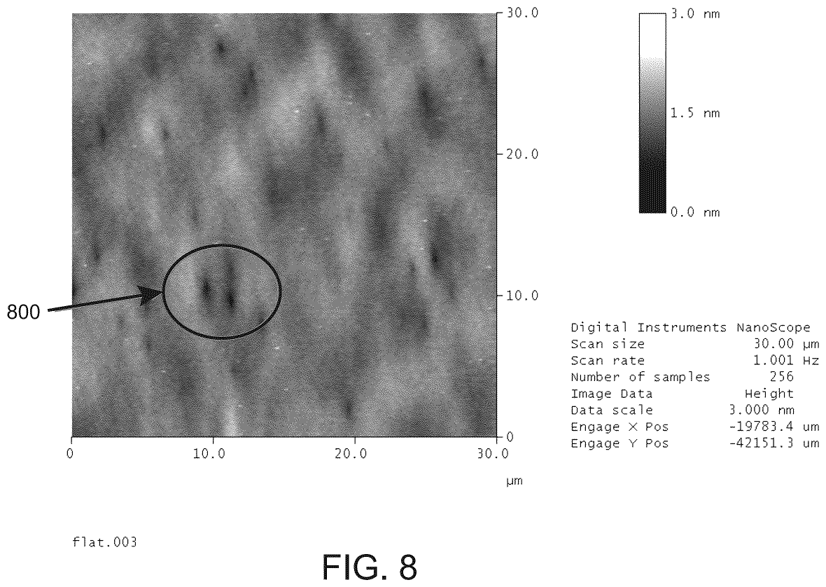

From AFM analysis, it has been discovered that many small nanometer-sized recesses are formed in top silicon device layers derived from conventional single crystal silicon donor substrates used in silicon-on-insulator manufacture. FIG. 8 is an AFM image (30 μm×30 μm scan size) taken from a transferred silicon device layer showing the nanometer-sized recesses (indicated at 800) that form during thermal smoothing anneal. These recesses (also referred to as “divets”) shown in the AFM image of FIG. 8 are localized low-thickness (or thin) spots on the silicon device layer where the thickness of the silicon device layer is reduced at the surface on a nanometer level. The presence of the divets contributes to higher surface roughness of the silicon device layer, and requires relatively extensive smoothing operations (e.g., CMP in conjunction with thermal anneal) to remove. Experiments were performed in an effort to eliminate these divets, to thereby achieve lower surface roughness of the silicon device layer post-anneal, and therefore minimize the additional processing that is otherwise needed to achieve the targeted surface roughness of the transferred silicon layer having the divets.

The effect that the underlying donor substrate has on the presence of these divets in a silicon device layer was tested using Perfect Silicon™ wafers commercially available from GlobalWafers Co., Ltd., Taiwan, and epitaxial silicon wafers as test donor wafers to produce silicon-on-insulator wafers. Perfect Silicon wafers are commonly used as donor wafers to prepare the silicon device layer in a silicon-on-insulator structure due to the lack of in-grown defects in these wafers. The epitaxial silicon wafers were prepared by depositing an epitaxial silicon layer on single crystal silicon wafers using an ASM Epsilon E3000 reactor. The thickness of the epitaxial silicon layers was between about 1 μm to about 3 μm. The silicon-on-insulator wafers were each prepared using SOI processing described herein including oxidation, implant, bond, and cleave. After cleave, thermal smoothing of each of the test silicon-on-insulator wafers was performed in an ASM A412 furnace. The conditions of the thermal smoothing for each silicon-on-insulator wafer was between 1000° C. to 1200° C., for a duration of between 1 hour to 3 hours, in an argon gas environment.

For comparison, the test donor wafers had different levels of nitrogen and oxygen and were sliced either on-axis or off-axis from a single crystal silicon ingot. Table 1 below summarizes the characteristics of each test donor wafer. Each of the test Perfect Silicon wafers had an interstitial oxygen concentration above 5 nppma (2.5×10¹⁷ atoms/cm³). Nitrogen doping and the axis angle at which the test Perfect Silicon wafers were sliced varied between the Perfect Silicon wafers. As shown in Table 1, each silicon device layer (tSi) transferred from the test Perfect Silicon wafers had detectable levels of oxygen. Whether the tSi layer transferred from the test Perfect Silicon wafer had detectable levels of nitrogen depends on whether the Perfect Silicon wafer was doped with nitrogen. One of the test epitaxial silicon wafers was sliced off-axis from an ingot, was doped with nitrogen, and had an interstitial oxygen concentration above 5 nppma (2.5×10¹⁷ atoms/cm³). The other test epitaxial silicon wafer was sliced on-axis from the ingot, had no nitrogen doping, and had an interstitial oxygen concentration below 5 nppma (2.5×10¹⁷ atoms/cm³). In each test epitaxial silicon wafer, oxygen and nitrogen were absent from the respective tSi layer, which may be attributed to the lack of oxygen and nitrogen formed in the deposited epitaxial silicon layer. Table 1 summarizes the results, showing whether the test donor wafers produced nanometer-sized recesses, or divets, in the respective silicon device layer post-thermal smoothing.

TABLE 1
Test results of whether divets are eliminated with different
types of donors used to make the SOI wafers

| | | | Oxygen in | | | |
|---|---|---|---|---|---|---|
| | On- | Nitrogen in | Substrate | Nitrogen in | Oxygen in | |
| Substrate Type | axis | Substrate | (nppma) | tSi | tSi | Divets? |
| Perfect Silicon | N | Y | 5-9 | Y | Y | Yes |
| Perfect Silicon | N | N | 5-9 | N | Y | Yes |
| Perfect Silicon | Y | Y | 5-9 | Y | Y | Yes |
| Epitaxial Wafer | N | Y | 5-9 | N | N | Yes |
| Epitaxial Wafer | Y | N | <5 | N | N | No |

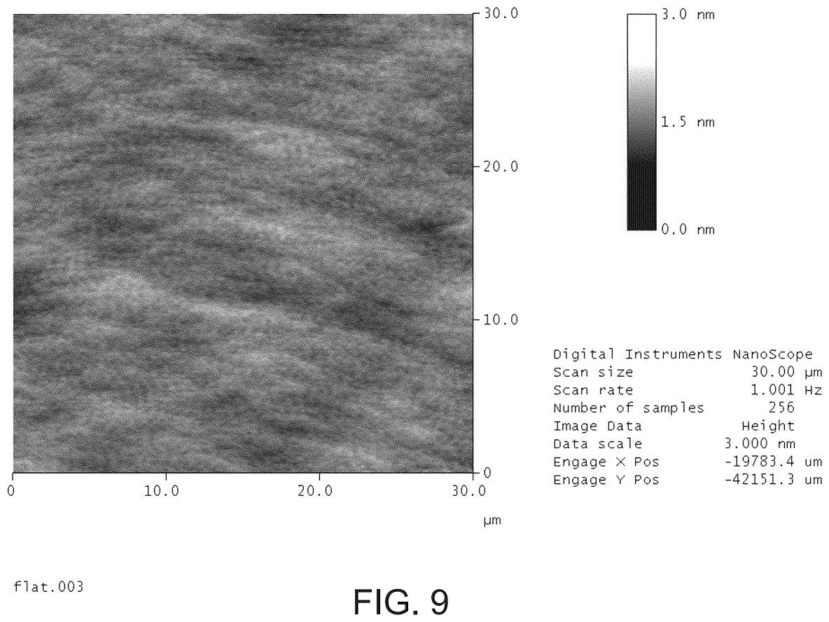

As shown in Table 1, of all the donor wafers tested, only the epitaxial donor wafer that was sliced on-axis from the ingot, had no nitrogen doping, and had an interstitial oxygen concentration below 5 nppma (2.5×10¹⁷ atoms/cm³) produced a tSi layer that lacked divets. The other test epitaxial silicon wafer, which was sliced off-axis from an ingot, was doped with nitrogen, and had an interstitial oxygen concentration above 5 nppma (2.5×10¹⁷ atoms/cm³), produced a tSi layer with divets. Each of the tSi layers from the test Perfect Silicon wafers had divets, regardless of nitrogen doping and slice angle. FIG. 9 depicts an AFM image (30 μm×30 μm scan size) taken from a tSi layer in which the divets (nanometer-sized recesses) were eliminated, i.e., did not form during thermal smoothing anneal, thus improving the surface roughness of the tSi layer.

As demonstrated, silicon device layers derived from epitaxial silicon layers have improved surface roughness post-thermal smoothing or post-anneal as compared to device layers derived from conventional single crystal silicon donor wafers. The comparative AFM analysis shows that the silicon device layers derived from standard wafers have post-anneal, nanometer-sized recesses or divets that affect the surface roughness, while the silicon device layers derived from epitaxial donor wafers lack these post-anneal, nanometer-sized recesses. Moreover, comparative AFM analysis between epitaxial donor wafers shows that the oxygen concentration, presence of nitrogen dopant, and/or slicing angle of the silicon donor wafers used to prepare the epitaxial donor wafer may affect the post-anneal surface roughness of the silicon layer transferred therefrom. In particular, AFM analysis shows that thin silicon layers derived from epitaxial donor wafers that have an interstitial oxygen concentration of less than 2.5×10¹⁷ atoms/cm³, are substantially free of nitrogen as dopant, and are sliced on-axis from a single crystal silicon ingot, lacked the post-anneal, nanometer-sized recesses or divets that affect the surface roughness.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” “front,” back,” etc.) is for convenience of description and does not require any particular orientation of the item described.

As various changes could be made in the above constructions and methods without departing from the scope of the disclosure, it is intended that all matter contained in the above description and shown in the accompanying drawing [s] shall be interpreted as illustrative and not in a limiting sense.

1. A method of preparing a silicon-on-insulator structure, the method comprising:
forming an epitaxial silicon layer on a front surface of a single crystal silicon donor substrate;
forming a dielectric layer on the epitaxial silicon layer to thereby form an epitaxial donor structure comprising the single crystal silicon donor substrate, the epitaxial silicon layer, and the dielectric layer;
bonding the dielectric layer of the epitaxial donor structure to a front surface of a handle structure, the handle structure comprising a single crystal semiconductor handle substrate, to thereby form a bonded structure comprising the handle structure, the dielectric layer, the epitaxial silicon layer, and the single crystal silicon donor substrate; and
removing the single crystal silicon donor substrate and a portion of the epitaxial silicon layer from the bonded structure to thereby form the silicon-on-insulator structure comprising the handle structure, the dielectric layer, and a silicon device layer.

2. The method of claim 1, further comprising annealing the silicon-on-insulator structure at a temperature and for a duration sufficient to smooth a surface of the silicon device layer.

3. The method of claim 2, wherein the annealing is performed at the temperature of between 1000° C. to 1200° C.

4. The method of claim 2, wherein the annealing is performed at the duration of between 15 minutes to 10 hours.

5. The method of claim 2, wherein the annealing is performed in the presence of an inert gas, hydrogen (H₂), or a combination thereof.

6. The method of claim 2, wherein a surface of the silicon device layer is characterized by a lack of nanometer-sized recesses that affect a roughness of the surface of the silicon device layer as measured by atomic force microscopy.

7. The method of claim 1, wherein the epitaxial silicon layer is substantially free of nitrogen.

8. The method of claim 1, wherein the epitaxial silicon layer is substantially free of oxygen.

9. The method of claim 1, wherein a thickness of the epitaxial silicon layer is between 0.5 μm to 5 μm.

10. The method of claim 1, wherein a thickness of the epitaxial silicon layer is between 1 μm to 3 μm.

11. The method of claim 1, wherein a thickness of the silicon device layer is less than 100 nm.

12. The method of claim 1, wherein a thickness of the silicon device layer is less than 25 nm.

13. The method of claim 1, wherein the single crystal silicon donor substrate is sliced substantially on-axis from a single crystal silicon ingot.

14. The method of claim 13, wherein on-axis deviation of an angle at which the single crystal silicon donor substrate is sliced from the single crystal silicon ingot is less than +/−0.1°.

15. The method of claim 13, wherein on-axis deviation of an angle at which the single crystal silicon donor substrate is sliced from the single crystal silicon ingot is less than +/−0.07°.

16. The method of claim 1, wherein the epitaxial silicon layer is formed by chemical vapor deposition.

17. The method of claim 1, wherein the single crystal silicon donor substrate has an interstitial oxygen concentration of less than 2.5×10¹⁷ atoms/cm³.

18. The method of claim 1, wherein the single crystal silicon donor substrate is substantially free of nitrogen as dopant.

19. The method of claim 1, wherein the method does not include chemical mechanical polishing of the silicon device layer.

20. The method of claim 1, further comprising implanting ions through a surface of the epitaxial donor structure to thereby form a cleave plane in the epitaxial silicon layer, wherein removing the single crystal silicon donor substrate and the portion of the epitaxial silicon layer from the bonded structure comprises cleaving the bonded structure at the cleave plane to thereby form the silicon-on-insulator structure.

21. A silicon-on-insulator structure comprising:
a handle structure comprising a handle substrate made of single crystal semiconductor material;
a dielectric layer in interfacial contact with a front surface of the handle structure; and
a silicon device layer in interfacial contact with the dielectric layer;
wherein the silicon-on-insulator structure is prepared by a method comprising:
forming an epitaxial silicon layer on a front surface of a single crystal silicon donor substrate;
forming the dielectric layer on the epitaxial silicon layer to thereby form an epitaxial donor structure comprising the single crystal silicon donor substrate, the epitaxial silicon layer, and the dielectric layer;
bonding the dielectric layer of the epitaxial donor structure to the front surface of the handle structure to thereby form a bonded structure comprising the handle structure, the dielectric layer, the epitaxial silicon layer, and the single crystal silicon donor substrate; and
removing the single crystal silicon donor substrate and a portion of the epitaxial silicon layer from the bonded structure to thereby form the silicon-on-insulator structure.
